(19) United States
(12) Patent Application Publication
(10) Pub. No.: US 2007/0284721 A1
(43) Pub. Date: Dec. 13, 2007

(54) Semiconductor device and method for producing the semiconductor device

(75) Inventor: Tatsuya Sakamoto, Fukuoka (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 11/802,675

(22) Filed: May 24, 2007

(30) Foreign Application Priority Data
May 26, 2006 (JP) 2006-147456

(51) Int. Cl. H01L 23/48

(52) U.S. Cl. 257/690

(57) ABSTRACT

A semiconductor device of the present invention is includes a semiconductor device comprising: a semiconductor chip having a passivation film on an electrode forming surface thereof on which a plurality of electrodes are formed; a protective film which is provided on an upper surface of the passivation film and patterned into a predetermined form; rewiring which is provided on an upper surface of each portion of the protective film divided by patterning and is connected to the electrode; a post connected to the rewiring; and a sealing resin layer which covers the rewiring.

### BACKGROUND OF THE INVENTION

1. Field of the Invention

The present invention relates to a semiconductor device and a method for producing the semiconductor device, and particularly, to a semiconductor device called a wafer level CSP (Chip Scale (or Size) Package) and a method for producing the semiconductor device.

2. Description of Related Art

Recently, use of low-k insulating films (having low dielectric constant) in semiconductor chips has been increased for higher performance. The low-k insulating film is mechanically fragile, so that as a method for electrically connecting a semiconductor chip including the low-k insulating film and the exterior, it is difficult to employ a connection method causing a comparatively great stress, such as using a bonding wire or a solder bump. To supply a sufficient drive current to the semiconductor chip, low-resistance wiring must be formed on the semiconductor chip.

Therefore, in some of such semiconductor chips, conductor-made posts and rewiring of conductive wiring which connects the posts and electrodes are provided on an electrode forming surface on which electrodes are formed, and the rewiring is covered by a sealing resin layer.

Particularly, by providing a protective film on the electrode forming surface of the semiconductor chip and forming posts on the upper surface of this protective film, the semiconductor chip is prevented from being greatly stressed via the posts when electrically connected to the exterior.

The protective film, the rewiring, the posts, and the sealing resin layer are formed before cutting and dividing a semiconductor substrate in a wafer state by dicing. By dividing the semiconductor substrate by dicing after forming the protective film, the rewiring, the posts, and the sealing resin layer, respective semiconductor devices are obtained. Such a semiconductor device is called a wafer level CSP or a wireless CSP.

The protective film, the rewiring, the posts, and the sealing resin layer are formed as follows in detail.

First, as shown in FIG. 8, on a semiconductor substrate having a predetermined circuit formed thereon, an electrode 110 is provided at a predetermined position. On the electrode forming surface of the semiconductor substrate 100 provided with this electrode 110, a passivation film 120 is formed. On the upper surface of the passivation film 120, a protective film 130 formed of a polyimide film is formed. The protective film 130 is formed by forming a polyimide film on the entire electrode forming surface of the semiconductor substrate 100 and patterning this polyimide film. By removing the polyimide film from the electrode 110 portion, the electrode 110 is exposed from the protective film 130.

After forming the protective film 130, Ar (argon) sputtering is performed to remove hydrogen and fluorine on the upper surface of the protective film 130 and leave carbon, whereby, as shown in FIG. 9, a carbon-rich conductive layer 140 is formed on the upper surface of the protective film 130. On the upper surface of this conductive layer 140, a barrier metal layer 150 is formed by copper sputtering. Thereafter, on the upper surface of the barrier metal layer 150, a rewiring 160 patterned into a predetermined form is formed. There wiring 160 is formed by forming copper coating by electrolytic plating processing on the upper surface of the barrier metal layer 150, forming a resist mask (not shown) patterned into a predetermined form on the upper surface of this copper coating, and etching the copper coating by using this resist mask. After forming the rewiring 160, the resist mask is removed.

After forming the rewiring 160, at predetermined positions of the rewiring 160, copper-made posts 170 are formed as shown in FIG. 10. After forming the posts 170, the barrier metal layer 150 used as a base for formation of the rewiring 160 is removed by etching. The posts 170 are formed by providing a dry film resist on the upper surface of the semiconductor substrate 100, forming openings at portions of the dry film resist where the posts 170 are to be formed, and forming copper coatings on the openings of the dry film resist by electrolytic plating processing. Thereafter, the dry film resist is removed.

If the conductive layer 140 is left after the barrier metal layer 150 is removed, all the posts 170 and the electrodes 110 are in a conduction state via the conductive layer 140, so that the conductive layer 140 is removed from the portions which are not covered by the rewiring 160 as shown in FIG. 11. The conductive layer 140 is in a conduction state due to carbon, so that the carbon must be removed. Therefore, the conductive layer 140 is removed by O₂ ashing.

After removing the conductive layer 140, a sealing resin layer 180 is formed on the upper surface of the semiconductor substrate 100. By this sealing resin layer 180, the rewiring 160 is sealed. Thereafter, by dicing, the semiconductor substrate 100 is cut and divided together with the sealing resin layer 180. Thereby, a wafer level CSP structured so that the protective film 130, the rewiring 160, and the posts 170 are provided within the sealing resin layer 180 is obtained.

When a carbon-rich conductive layer is formed by Ar sputtering on the upper surface of the protective film on which the barrier metal layer is to be formed, before forming the barrier metal layer as a base for formation of the rewiring, the barrier metal layer can be firmly bonded to the protective film via the conductive layer. However, the conductive layer that becomes unnecessary after forming the posts must be removed, so that O₂ ashing is essential.

If this O₂ ashing processing is insufficient or the process of O₂ ashing is skipped, the posts may become electrically conducted to each other due to the remaining conductive layer, and this may cause short-circuiting.

It is difficult to judge the finish of O₂ ashing processing, and therefore, to reliably remove the conductive layer, the O₂ ashing processing time at a low temperature of not more than 80° C. must be set long. However, such a setting easily causes the protective film to crack, and may cause a leakage.

### SUMMARY OF THE INVENTION

The semiconductor device of the present invention includes a semiconductor chip including a passivation film on an electrode forming surface thereof on which a plurality of electrodes are formed, a protective film which is provided on an upper surface of the passivation film and patterned into a predetermined form, rewiring which is provided on an upper surface of respective portion of the protective film divided by patterning and is electrically connected to the electrode, a post connected to the rewiring, and a sealing resin layer which covers the rewiring.

With this construction, the protective film is divided into respective portions, and rewiring is provided on the upper surfaces of the respective divided portions. Accordingly, the conductive layers formed on the upper surfaces of the protective films can be reliably divided. As a result, short-circuiting can be prevented.

Conventionally, to prevent short-circuiting, the conductive film must be removed by O₂ ashing processing. On the other hand, with the above construction, the protective film is divided into respective portions, so that the conductive film which causes short-circuiting is not formed. Therefore, O₂ ashing processing can be skipped, the number of processes can be reduced, and the protective film can be prevented from being damaged by O₂ ashing processing. Therefore, leak checks for checking the damage of the protective film in the O₂ ashing processing can be omitted, so that the number of processes can be reduced further.

The semiconductor device can be produced according to a method for producing the semiconductor device comprising the steps of: preparing a semiconductor chip having a passivation film on an electrode forming surface thereof on which a plurality of electrodes are provided and forming a protective film on an upper surface of the passivation film; forming rewiring connected to the electrode on an upper surface of the protective film; forming a post connected to the rewiring; forming a sealing resin layer for covering the rewiring; and removing the protective film positioned between rewiring forming regions in which the rewiring is formed.

The protective film positioned between the rewiring forming regions may be removed concurrently with patterning for forming openings from which the electrodes are exposed in the protective film formed on the entire upper surface of the passivation film.

The above-described and other objects, features, and effects of the present invention will be made clear from the following description of an embodiment with reference to the accompanying drawings.

### BRIEF DESCRIPTION OF THE DRAWINGS

FIG. 1 is a schematic sectional view of a main portion of a semiconductor device according to an embodiment of the present invention;

FIG. 2 is a schematic sectional view for describing the production process of the semiconductor device;

FIG. 3 is a schematic sectional view for describing the production process of the semiconductor device;

FIG. 4 is a schematic sectional view for describing the production process of the semiconductor device;

FIG. 5 is a schematic sectional view for describing the production process of the semiconductor device;

FIG. 6 is a schematic sectional view for describing the production process of the semiconductor device;

FIG. 7 is a schematic sectional view for describing the production process of the semiconductor device;

FIG. 8 is a schematic sectional view for describing a production process of a conventional semiconductor device;

FIG. 9 is a schematic sectional view for describing the production process of the conventional semiconductor device;

FIG. 10 is a schematic sectional view for describing the production process of the conventional semiconductor device;

FIG. 11 is a schematic sectional view for describing the production process of the conventional semiconductor device;

FIG. 12 is a schematic sectional view for describing the production process of the conventional semiconductor device.

### DETAILED DESCRIPTION OF PREFERRED EMBODIMENT

A semiconductor device of the present invention is composed of a semiconductor chip called a wafer level CSP and a sealing resin layer which overlaps one surface of the semiconductor chip in the thickness direction. In the sealing resin layer, posts to be used for electrical connection to the exterior, rewiring connected to both of the posts and electrodes of the semiconductor chip, and a protective film serving as a base of the rewiring are provided.

Particularly, conventionally, the protective film is provided so as to cover the entirety of the semiconductor chip except for the electrodes independently of the pattern of the rewiring. On the other hand, in the present invention, the protective film is divided to be independent for each wiring by patterning according to rewiring patterning.

That is, between adjacent rewirings, a groove is formed by removing the protective film. When forming a carbon-rich conductive layer on the upper surface of the protective film by Ar sputtering, the conductive layer is not formed at the groove portion. Accordingly, the respective conductive layers can be completely divided by the grooves.

Therefore, O₂ ashing processing for removing the conductive layer is made unnecessary, and the process can be shortened. Further, due to omission of O₂ ashing processing, the protective film can be prevented from being damaged by O₂ ashing processing. In addition, leak checks for checking the degree of this damage can be omitted, and the process can be shortened further.

Hereinafter, an embodiment of the present invention will be described in detail with reference to the drawings.

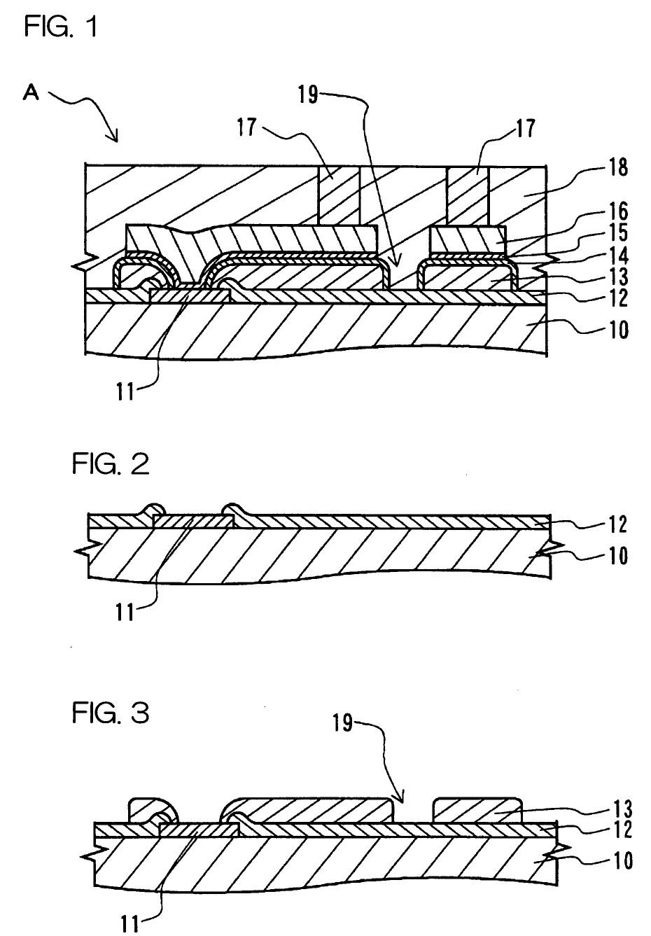

FIG. 1 is a schematic sectional view of a main portion of a semiconductor device A according to the present embodiment.

The semiconductor device A of the present embodiment includes a semiconductor chip 10 having a passivation film 12 on an electrode forming surface thereof on which a plurality of electrodes 11 are formed, a protective film 13 which is provided on the upper surface of the passivation film 12 and patterned into a predetermined form, rewiring 16 which is provided on the upper surfaces of the respective protective films 13 divided into respective portions by grooves 19 and is connected to the electrodes 11, posts 17 connected to the rewiring 16, and a sealing resin layer 18 which covers the rewiring 16.

On the upper surfaces of the respective protective films 13 divided by grooves 19, a conductive layer 14 and a barrier metal layer 150 are provided. The conductive layer 14 is electrically isolated for each protective film 13 by providing the grooves 19 between the protective films 13.

Therefore, the rewirings 16 on the protective films 13 adjacent to each other are not short-circuited via the conductive layer 14, so that short-circuiting can be prevented.

Hereinafter, a method for producing the sealing resin layer 18 portion will be described in detail.

First, as shown in FIG. 2, on a semiconductor substrate 10 having a predetermined circuit formed thereon, the electrodes 11 are provided at predetermined positions. On the electrode forming surface of the semiconductor substrate 10 on which the electrodes 11 are provided, the passivation film 12 is provided. At this point in time, the semiconductor substrate 10 is in a wafer state before being divided into semiconductor chips by dicing.

The semiconductor substrate 10 thus provided with the passivation film 12 is used. As shown in FIG. 3, on the passivation film 12, a polyimide film is formed to serve as the protective film 13. In detail, on the upper surface of the semiconductor substrate 10, a polyimide solution that forms a polyimide film is coated by means of spin-coating or the like. Successively, a predetermined mask is set on the upper surface of the semiconductor substrate 10, and the mask is irradiated with ultraviolet rays, whereby the polyimide solution at the portion irradiated with ultra violet rays is cured. Thereafter, the uncured polyimide solution is removed by washing and the cured portion is left to form the protective film 13 made of a polyimide film in a predetermined pattern.

In a conventional production method, the polyimide solution coated on the semiconductor substrate 10 was entirely cured except for the electrode 11 portions of the semiconductor substrate 10. On the other hand, in the present embodiment, the polyimide film patterned according to the forming pattern of the rewiring 16 is formed, whereby the grooves 19 are formed by removing the protective film between rewiring forming regions in which the rewiring 16 is formed. Therefore, the protective film 13 is provided at least as many as the number of rewirings 16. Moreover, between the protective films 13, the grooves 19 with a predetermined width are provided, and the width of the grooves 19 is desirably as wide as possible. In the patterned polyimide film forming process, the grooves 19 are formed by removing the uncured polyimide solution, so that this process of removing the uncured polyimide solution corresponds to the process of removing the protective film positioned between the rewiring forming regions in which rewiring 16 is formed.

Particularly, when forming the protective film 13, concurrently with patterning for forming the openings from which the electrodes 11 are exposed, patterning for forming the grooves 19 for dividing the protective film 13 into respective portions is performed and the protective film positioned between the rewiring forming regions is removed, whereby the protective film 13 can be divided without adding a new production process.

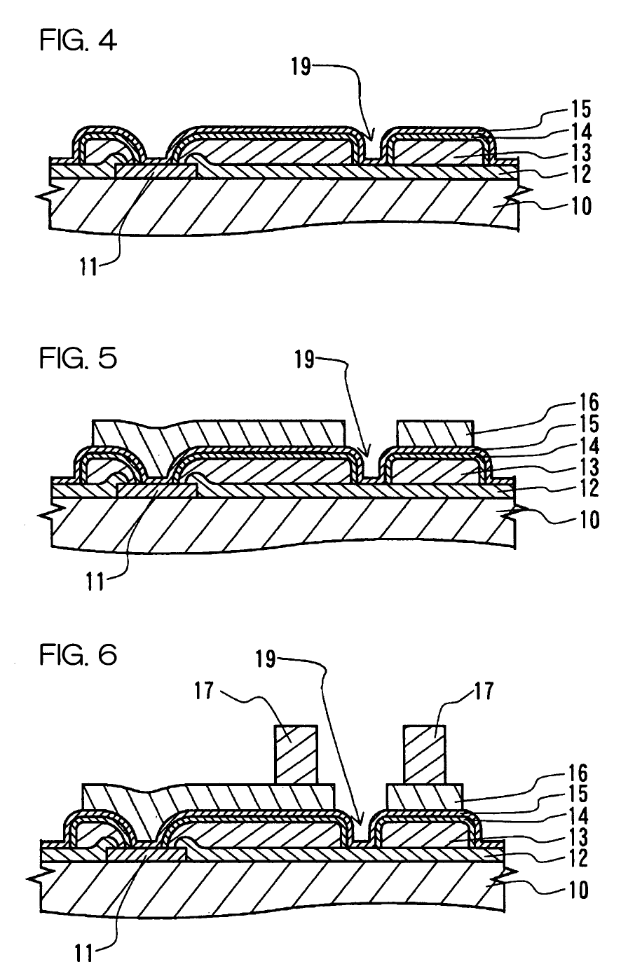

After forming the protective film 13, Ar sputtering is performed and hydrogen and fluorine on the upper surface of the protective film 13 are removed and carbon is left, whereby, as shown in FIG. 4, the carbon-rich conductive layer 14 is formed on the upper surface of the protective film 13. On the upper surface of the conductive layer 14, the barrier metal layer 15 is formed by copper sputtering. The barrier metal layer 15 is firmly bonded to the protective film 13 via the conductive layer 14.

When forming the conductive layer 14, at the groove portions between adjacent protective films 13, no carbon is left, so that the conductive layer 14 is not formed.

After forming the barrier metal layer 15, as shown in FIG. 5, on the upper surface of the barrier metal layer 15, the rewiring 16 patterned into a predetermined form is formed. Each rewiring 16 is formed on one protective film 13.

To form the rewiring 16 on the divided protective films 13, first, on the upper surface of the barrier metal layer 15, copper coating is formed by electrolytic plating processing. Then, on the upper surface of this copper coating, a resist mask (not shown) patterned into a predetermined form is formed. Thereafter, by etching the copper coating by using this resist mask, the rewiring 16 is formed. By adjusting the form of the resist mask, the rewiring 16 can be provided on the protective film 13. After forming the rewiring 16, the resist mask is removed.

After forming the rewiring 16, as shown in FIG. 6, at predetermined positions of the rewiring 16, the copper-made posts 17 are formed.

This post 17 is formed by providing a dry film resist (not shown) on the upper surface of the semiconductor substrate 10, forming an opening at a portion where the post 17 is formed in this dry film resist, and performing electrolytic plating processing to form a plating film on the opening portion of the dry film resist. After forming the post 17, the dry film resist is removed.

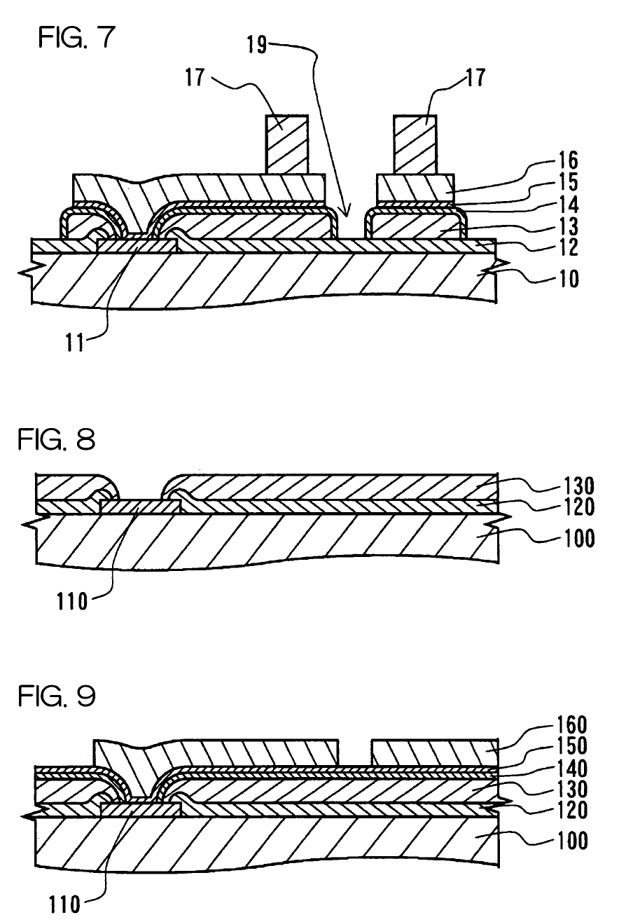

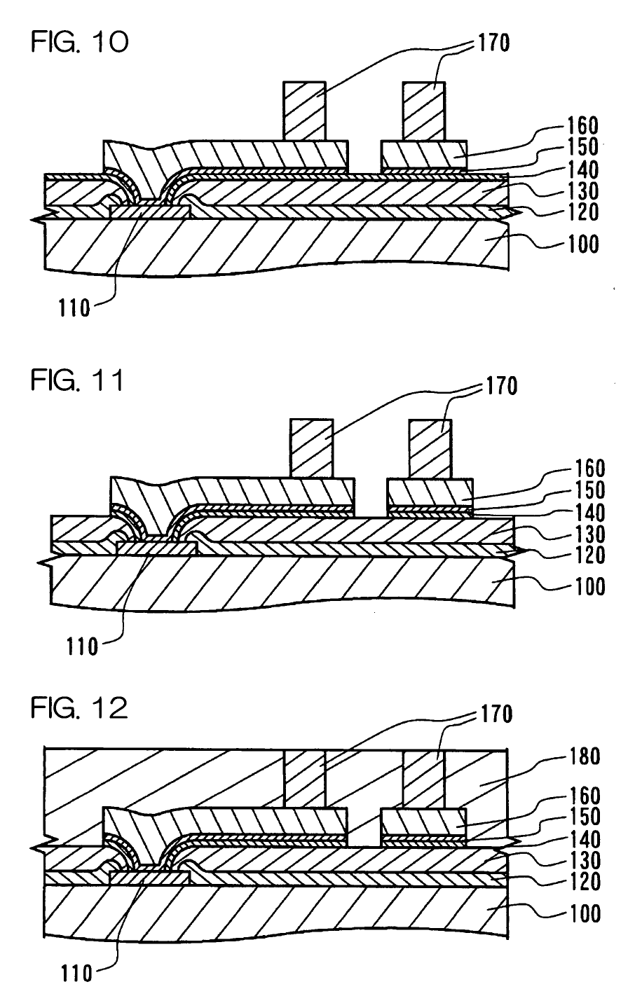

After forming the post 17, as shown in FIG. 7, the barrier metal layer 15 used as a base of formation of the rewiring 16 is removed by etching. By removing the barrier metal layer 15, each rewiring 16 on the protective film 13 is independently electrically insulated from other rewiring 16. Therefore, no short-circuiting occurs between each rewiring 16 and other rewiring 16.

Thus, according to removal of the barrier metal layer 15, each rewiring 16 is insulated from other rewiring 16 without performing O₂ ashing. Thereafter, a resin that becomes the sealing resin layer 18 is coated on the upper surface of the semiconductor substrate 10 and cured, whereby the sealing resin layer 18 which seals the rewiring 16 is formed as shown in FIG. 1.

When forming the sealing resin layer 18, the upper surfaces of the protective films 13 that are not covered by the rewiring 16 are covered by the conductive layer 14 which has become porous, so that due to its anchoring effect, the conductive layer 14 and the sealing resin layer 18 can be brought into close contact with each other. As a result, the close contact strength of the sealing resin layer 18 can be improved.

By dicing the semiconductor substrate 10 in which the sealing resin layer 18 is formed, the respective semiconductor devices A can be formed.

The conductive layer 14 on the protective film 13 that is not covered by the rewiring 16 can also be used as an extraction wiring. When the semiconductor substrate 10 on which the sealing resin layer 18 is formed is diced into the semiconductor devices A, dicing is performed so that the conductive layer 14 is exposed, and the resulting cut surface is coated with an electrode material and is made into a conduction state with the conductive layer 14, whereby the electrode provided on this cut surface can be used as a ground.

Although the embodiment of the present invention is described in detail above, the embodiment is merely a detailed example used for making clear the technical contents of the present invention, the present invention should not be interpreted to be limited to this detailed example, and the spirit and scope of the present invention are limited only by the accompanying claims.

The present application corresponds to Japanese Patent Application No. 2006-147456 filed with the Japanese Patent Office on May 26, 2006, the disclosure of which is incorporated herein by reference.

What is claimed is:

1. A semiconductor device comprising:
a semiconductor chip having a passivation film on an electrode forming surface thereof on which a plurality of electrodes are formed;
a protective film which is provided on an upper surface of the passivation film and patterned into a predetermined form;
rewiring which is provided on an upper surface of each portion of the protective film divided by patterning and is connected to the electrode;
a post connected to the rewiring; and
a sealing resin layer which covers the rewiring.

2. A method for producing a semiconductor device comprising the steps of:
preparing a semiconductor chip having a passivation film on an electrode forming surface thereof on which a plurality of electrodes are provided, and forming a protective film on an upper surface of the passivation film;
forming rewiring connected to the electrode, on an upper surface of the protective film;
forming a post connected to the rewiring;
forming a sealing resin layer which covers the rewiring; and
removing the protective film positioned between rewiring forming regions in which the rewiring is formed.

3. The method for producing a semiconductor device according to claim 2, wherein
the removing step of the protective film positioned between the rewiring forming regions is performed concurrently with patterning for forming an opening from which the electrode is exposed in the protective film formed on the entire upper surface of the passivation film.
